(19) United States
(12) Patent Application Publication
(10) Pub. No.: US 2011/0240345 A1
(43) Pub. Date: Oct. 6, 2011

(54) PRINTED CIRCUIT BOARD AND METHOD FOR MAKING SAME

(75) Inventor: CHI-KUNG SU, Tu-Cheng (TW)

(73) Assignee: HON HAI PRECISION INDUSTRY CO., LTD., Tu-Cheng (TW)

(21) Appl. No.: 12/764,963

(22) Filed: Apr. 22, 2010

(30) Foreign Application Priority Data
Apr. 1, 2010 (TW) 99110228

(51) Int. Cl. H05K 1/09; B32B 37/00

(52) U.S. Cl. 174/257; 156/60; 156/62.2

(57) ABSTRACT

A printed circuit board (PCB) includes a base, copper foils, an insulating layer, and metallic foils. The copper foils are disposed on the base. The insulating layer is coated on the copper foils. The metallic foils are layered on the insulating layer. The copper foils and the metallic foils connect a first electrical element to a second electrical element.

### BACKGROUND

1. Technical Field

The present disclosure relates to a printed circuit board (PCB) and a method for making the same.

2. Description of Related Art

Generally, a central processing unit (CPU) and a power supply managing circuit are disposed on a printed circuit board (PCB) of a computer and connected to each other via a plurality of copper foils. A heat sink is disposed on the CPU for heat dissipation of the CPU. The volume of the heat sink is typically larger than the CPU. Therefore, it is necessary to leave a space between the CPU and the power supply managing circuit to position the heat sink. As a result, the copper foils are undesirably elongated, resulting in a larger resistance of the copper foils and accordingly a larger amount of power loss.

Therefore, it is desirable to provide a PCB, which can overcome the above-discussed shortcomings.

### BRIEF DESCRIPTION OF THE DRAWINGS

Many aspects of the embodiments should be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a cross-sectional view of a printed circuit board (PCB) according to the disclosure.

FIG. 2 is a circuit diagram of the PCB of FIG. 1.

FIG. 3 is a flow chart of a method of making the PCB of FIG. 1.

### DETAILED DESCRIPTION

Referring to FIG. 1, a printed circuit board (PCB) 1, according to a disclosure, is configured for connecting a first electrical element to a second electrical element. In the present disclosure, the first electrical element is a CPU 2. The second electrical element is a power supply managing circuit 3. The CPU 2 includes a plurality of input pins 21. The power supply managing circuit 3 is electrically connected to a power supply (not shown) and configured for adjusting the voltage of the power supply to make the CPU 2 to work at a rated voltage and a rated current. The power supply managing circuit 3 includes a plurality of output pins 31. The PCB 1 includes a base 10, a plurality of copper foils 11, an insulating layer 12, and a plurality of metallic foils 13.

The insulating layer 12 is coated on the copper foils 11. The metallic foils 13, such as tin foils, are coated on the insulating layer 12. The copper foils 11 and the metallic foils 13 are used for connecting the output pins 31 of the power supply managing circuit 3 to the corresponding input pins 21 of the CPU 2 in parallel.

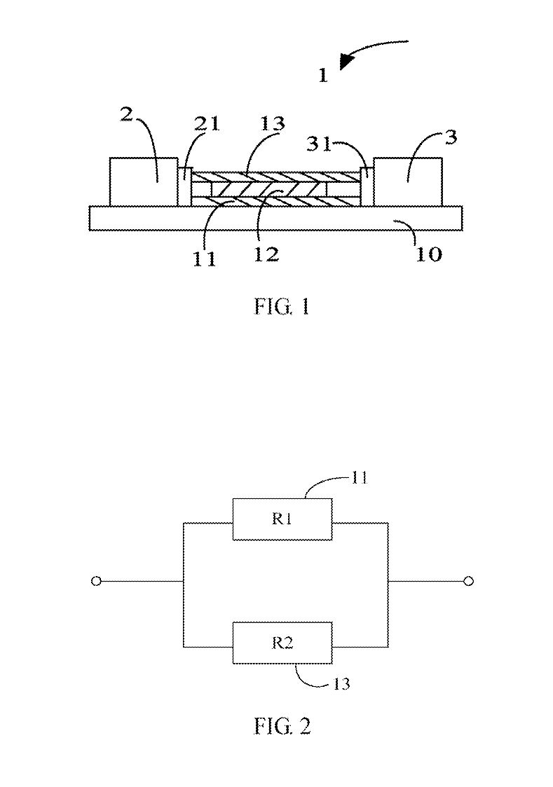

Referring to FIG. 2, the resistance of the copper foils 11 is represented as R1. The resistance of the metallic foils 13 is represented as R2. The copper foils 11 are parallelly and electrically connected to the metallic foils 13. As such, the total resistance of the copper foils 11 and the metallic foils 13 is R=R1R2/(R1+R2). It is obvious that R will always be smaller than the R1. The power consumption of the copper foils 11 and the metallic foils 13 is: P=I²R, where P is the power consumption and I is the rated current of the CPU 2. Obviously, power loss is reduced.

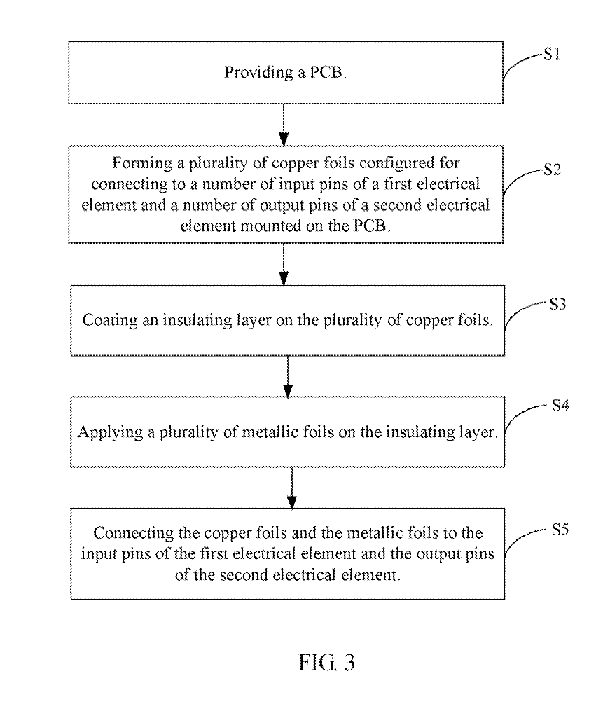

Referring to FIG. 3, a method of making the PCB is shown. The method includes the following steps:

S1: providing a PCB 1.

S2: Forming a plurality of copper foils 11 configured for connecting to a number of input pins 21 of a first electrical element 2 and a number of output pins 31 of a second electrical element 3 mounted on the PCB 1. In the present disclosure, the first electrical element is a CPU, while the second electrical element is a power supply managing circuit.

S3: coating an insulating layer 12 on the plurality of copper foils 11. In the present disclosure, the insulating layer 12 is made of scaling powder.

S4: applying a plurality of metallic foils 13 on the insulating layer 12.

S5: connecting the copper foils 11 and the metallic foils 13 to the input pins 21 of the first electrical element 2 and the output pins 31 of the second electrical element 3. In the present disclosure, the metallic foils 13 are made of tin foil.

It will be understood that the above particular embodiments and methods are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A printed circuit board (PCB) comprising:
a base;
a plurality of copper foils disposed on the base;
an insulating layer coated on the copper foils;
a plurality of metallic foils coated on the insulating layer;
wherein the copper foils and the metallic foils are electrically connect a first electrical element and a second electrical element.

2. The PCB in claim 1, wherein the metallic foils are made of tin foil.

3. The PCB in claim 2, wherein the insulating layer is made of scaling powder.

4. The PCB in claim 1, wherein the first electrical element is a CPU, and the second electrical element is a power supply managing circuit.

5. A method of making a PCB comprising the following:
providing a PCB;
forming a plurality of copper foils configured for connecting a first electrical element and a second electrical element mounted on the PCB;
coating an insulating layer on the plurality of copper foils;
applying a plurality of metallic foils on the insulating layer; and
connecting the copper foils and the metallic foils to the first electrical element and the second electrical element.

6. The method of making a PCB in claim 5, wherein the metallic foils is made of tin foil.

7. The method of making a PCB in claim 6, wherein the insulating layer is made of scaling powder.

8. The method of making a PCB in claim 5, wherein the first electrical element is a CPU, while the second electrical element is a power supply managing circuit.
